(19) United States
(12) Patent Application Publication
(10) Pub. No.: US 2012/0009795 A1
(43) Pub. Date: Jan. 12, 2012

(54) CHEMICALLY AMPLIFIED RESIST MATERIAL AND PATTERN FORMATION METHOD USING THE SAME

(75) Inventors: Masayuki ENDOU, Osaka (JP); Masaru Sasago, Osaka (JP)

(73) Assignee: PANASONIC CORPORATION, Osaka (JP)

(21) Appl. No.: 13/237,657

(22) Filed: Sep. 20, 2011

Related U.S. Application Data
(63) Continuation of application No. PCT/JP2010/000191, filed on Jan. 15, 2010.

(30) Foreign Application Priority Data
Mar. 30, 2009 (JP) 2009-081433

(51) Int. Cl. H01L 21/311; C08F 120/30; C08F 116/14; G03F 7/20

(52) U.S. Cl. 438/703; 430/325; 430/296; 525/327.2; 257/E21.257

(57) ABSTRACT

A resist film (102) made of a chemically amplified resist material including a polymer containing an acid leaving group and a group in which a lactone is replaced with hydrogen in an OH group of phenol is formed on a substrate (101). The resist film (102) is then selectively irradiated with exposure light, thereby performing pattern exposure. After the pattern exposure, the resist film (102) is heated, and then developed, thereby forming a resist pattern (102a) out of the resist film (102).

### CROSS-REFERENCE TO RELATED APPLICATION

This is a continuation of PCT International Application PCT/JP2010/000191 filed on Jan. 15, 2010, which claims priority to Japanese Patent Application No. 2009-081433 filed on Mar. 30, 2009. The disclosures of these applications including the specifications, the drawings, and the claims are hereby incorporated by reference in their entirety.

### BACKGROUND

The present disclosure relates to chemically amplified resist materials for use in, for example, fabrication processes of semiconductor devices, and pattern formation methods using such resist materials.

With increasing integration of semiconductor integrated circuits and downsizing of semiconductor elements, there has been a demand for acceleration of the development of lithography techniques. At present, pattern formation is performed by photolithography using mercury lamps, KrF excimer lasers, ArF excimer lasers, or the like, as sources of exposure light. In recent years, use of extreme ultraviolet light with shorter wavelengths of exposure light has been taken into consideration. Extreme ultraviolet light has a short wavelength of 13.5 nm, which is 1/10 or less of light used in conventional photolithography. Thus, use of extreme ultraviolet light is expected to achieve a considerable increase in resolution.

Formation of fine patterns including exposure to such extreme ultraviolet light and immersion lithography employs chemically amplified resists. A chemically amplified resist is a resist essential for an increase in resolution. An acid is generated with exposure light from a photoacid generator in a resist, and the generated acid causes chemical reaction in the resist, thereby leading to pattern formation.

A conventional pattern formation method will be described hereinafter with reference to FIGS. 5A-5D and 6.

First, a chemically amplified positive resist material having the following composition is prepared.

Base polymer: poly(2-methyl-2-adamanthyl methacrylate (50 mol %)-γ-butyrolactone methacrylate (40 mol %)-2-hydroxy adamantane methacrylate (10 mol %)) . . . 2 g

Photoacid generator: triphenylsulfonium trifluoromethanesulfonic acid . . . 0.05 g

Quencher: triethanolamine . . . 0.002 g

Solvent: propylene glycol monomethyl ether acetate . . . 20 g

Next, as shown in FIG. 5A, the chemically amplified resist material is applied on a substrate 1, and then is heated at a temperature of 90° C. for 60 seconds, thereby forming a resist film 2 with a thickness of 60 nm.

Then, as shown in FIG. 5B, the resist film 2 is irradiated with exposure light of extreme ultraviolet light (EUV) having a numerical aperture (NA) of 0.25 and a wavelength of 13.5 nm through a mask (not shown), thereby performing pattern exposure.

After the pattern exposure, as shown in FIG. 5C, the resist film 2 is heated with a hot plate at a temperature of 105° C. for 60 seconds.

Thereafter, the heated resist film 2 is developed with a 2.38 wt. % tetramethylammonium hydroxide developer, thereby obtaining a resist pattern 2a made of an unexposed portion of the resist film 2 and having a line width of 30 nm, as shown in FIG. 5D.

### SUMMARY

The pattern formation method using the conventional chemically amplified resist material, however, has a problem of a high degree of roughness (e.g., 8 nm with a standard deviation (3σ)) of the resultant resist pattern 2a as shown in FIGS. 5D and 6.

In this manner, etching on a target film using the resist pattern 2a with a defective shape causes the pattern shape obtained from the target film to be defective, thereby reducing productivity and the yield in processes of fabricating semiconductor devices.

It is therefore an object of the present disclosure to obtain a pattern formation method for forming a resist pattern with a desired shape by reducing roughness occurring in a resist pattern.

The inventors of the present disclosure conducted various studies on causes of roughness in forming miniaturized patterns, to obtain the following conclusion. Specifically, roughness of the pattern is due to a relatively large scale diffusion of an acid from a photoacid generator after light exposure, with respect to a miniaturized pattern size. More specifically, as described in T. Kudo et al., “Illumination, Acid Diffusion and Process Optimization Considerations for 193 nm Contact Hole Resists,” Proc. SPIE, vol. 4690, p. 150 (2002), in a lactone used in a conventional chemically amplified resist material and replaced with hydrogen in a COOH group added to increase adhesiveness of a resist, an acid is easily transmitted because of steric movableness of the COO group, and thus acid diffusion increases (see [Chemical Formula 1]).

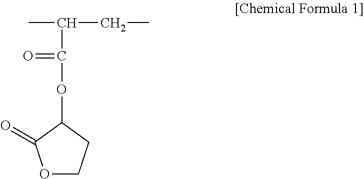

The inventors of the present disclosure further conducted studies on the aforementioned conclusion, to find that replacement of a lactone with hydrogen in the OH group of phenol reduces acid diffusion (see [Chemical Formula 2]). Specifically, since the OH group of phenol is spatially stable, transmission of an acid is restricted, and in addition, the acid is trapped by unpaired electrons in cyclic ester of the lactone. Accordingly, diffusion of the acid is reduced, thereby reducing roughness of a miniaturized pattern. For example, in a conventional case in which acid diffusion is not controlled, the acid diffusion distance is as large as about 10 nm. However, according to the present disclosure, the acid diffusion distance can be reduced to the range from about 2 nm to about 3 nm, both inclusive.

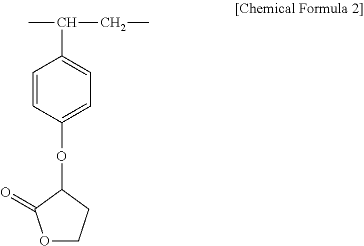

The lactone replaced with hydrogen in the COOH group shown in [Chemical Formula 1] may be contained in a polymer containing the lactone replaced with hydrogen in the OH group of phenol shown in [Chemical Formula 2], or may be added as another polymer. In these cases, the lactone replaced with hydrogen in the COOH group is preferably less than or equal to about 30 weight percent (wt. %) of the lactone replaced with hydrogen in the OH group of phenol so as not to reduce the effects of the lactone replaced with hydrogen in the OH group of phenol.

In addition, according to the present disclosure, since acid diffusion is reduced, the thickness of a resist film is reduced, and thus pattern formation can be more easily performed. Specifically, for example, a multilayer resist process using a lower film and an intermediate film can be performed. The multilayer resist process is significantly effective in the case of using a resist material showing small distribution of an acid as in the present disclosure.

Based on the foregoing findings, the present disclosure has been achieved in the following manner.

A chemically amplified resist material according to the present disclosure includes a polymer containing an acid leaving group and a group in which a lactone is replaced with hydrogen in an OH group of phenol.

The chemically amplified resist material of the present disclosure includes a group in which a lactone is replaced with hydrogen in an OH group of phenol, and the OH group of phenol is spatially stable. Thus, transmission of an acid is restricted. In addition, since the acid is trapped by unpaired electrons in cyclic ester of the lactone, diffusion of the acid is reduced, and the generated acid reacts with an adjacent acid leaving group. Consequently, roughness of a miniaturized pattern is reduced, thus obtaining a fine pattern with a desired shape. The location of replacement of a lactone with hydrogen in the OH group of phenol is not specifically limited.

In the chemically amplified resist material, the lactone may be one of α-lactone, β-lactone, γ-lactone, or δ-lactone.

In this case, the α-lactone may be α-ethylolactone, the β-lactone may be β-propylolactone, the γ-lactone may be γ-butyrolactone, and the δ-lactone my be δ-pentylolactone.

In the chemically amplified resist material, the acid leaving group may be one of an acetal group, a cyclohexylmethyl group, a cyclohexylethyl group, a cyclopentylmethyl group, or a cyclopentylethyl group.

In this case, the acetal group may be one of a 1-ethoxyethyl group, a methoxymethyl group, or a 1-ethoxymethyl group.

In this manner, use of an acid leaving group with low activation energy can reduce the influence on acid elimination reaction even with occurrence of an acid trap in an exposed portion of the resist film.

A pattern formation method according to a first aspect includes the steps of: forming a resist film on a substrate, the resist film being made of a chemically amplified resist material including a polymer containing an acid leaving group and a group in which a lactone is replaced with hydrogen in an OH group of phenol; selectively irradiating the resist film with exposure light, thereby performing pattern exposure; heating the resist film subjected to the pattern exposure; and developing the heated resist film, thereby forming a resist pattern out of the resist film.

In the pattern formation method of the first aspect, the chemically amplified resist material includes a polymer containing an acid leaving group and a group in which a lactone is replaced with hydrogen in an OH group of phenol. Since the OH group of phenol is spatially stable, transmission of an acid is restricted. In addition, the acid is trapped by unpaired electrons in cyclic ester of the lactone, and thus diffusion of the acid is reduced. The generated acid reacts with an adjacent acid leaving group. Consequently, roughness of a miniaturized pattern is reduced, thus obtaining a fine pattern with a desired shape.

A pattern formation method according to a second aspect includes the steps of: forming a lower film on a substrate; forming an intermediate film on the lower film; forming a resist film on the intermediate film, the resist film being made of a chemically amplified resist material including a polymer containing an acid leaving group and a group in which a lactone is replaced with hydrogen in an OH group of phenol; selectively irradiating the resist film with exposure light, thereby performing pattern exposure; heating the resist film subjected to the pattern exposure; developing the heated resist film, thereby forming a resist pattern out of the resist film; etching the intermediate film using the resist pattern as a mask, thereby forming a first pattern out of the intermediate film; and etching the lower film using the first pattern as a mask, thereby forming a second pattern out of the lower film.

In the pattern formation method of the second aspect, in the multilayer resist process, the chemically amplified resist material includes a polymer containing an acid leaving group and a group in which a lactone is replaced with hydrogen in an OH group of phenol. Since the OH group of phenol is spatially stable, transmission of an acid is restricted. In addition, the acid is trapped by unpaired electrons in cyclic ester of the lactone, and thus diffusion of the acid is reduced. The generated acid reacts with an adjacent acid leaving group. Consequently, roughness of a miniaturized pattern is reduced, thus obtaining a resist pattern with a desired shape and a smaller thickness. Out of the resist pattern with a desired shape, a first pattern and a second pattern with desired shapes can be formed.

In the pattern formation method of the second aspect, the lower film may be a hard-baked organic film. Then, etching resistance can be achieved in a treatment on the substrate.

In the pattern formation method of the second aspect, the intermediate film may be made of either silicon oxide or a precursor of silicon oxide. Then, the lower film can have etching resistance.

In the pattern formation method of the first or second aspect, the exposure light may be one of extreme ultraviolet light, an electron beam, or KrF excimer laser light.

With the chemically amplified resist material and the pattern formation methods using the material according to the present disclosure, roughness occurring in a resist pattern can be reduced, thereby obtaining a fine pattern with a desired shape.

### BRIEF DESCRIPTION OF THE DRAWINGS

FIGS. 1A-1D are cross-sectional views showing respective process steps of a pattern formation method according to a first exemplary embodiment of the present disclosure.

FIG. 2 is a plan view showing a resist pattern obtained with the pattern formation method of the first exemplary embodiment.

FIGS. 3A-3D are cross-sectional views showing respective process steps of a pattern formation method according to a second exemplary embodiment of the present disclosure.

FIGS. 4A-4D are cross-sectional views showing respective process steps of the pattern formation method of the second exemplary embodiment.

FIGS. 5A-5D are cross-sectional views showing respective process steps of a conventional pattern formation method.

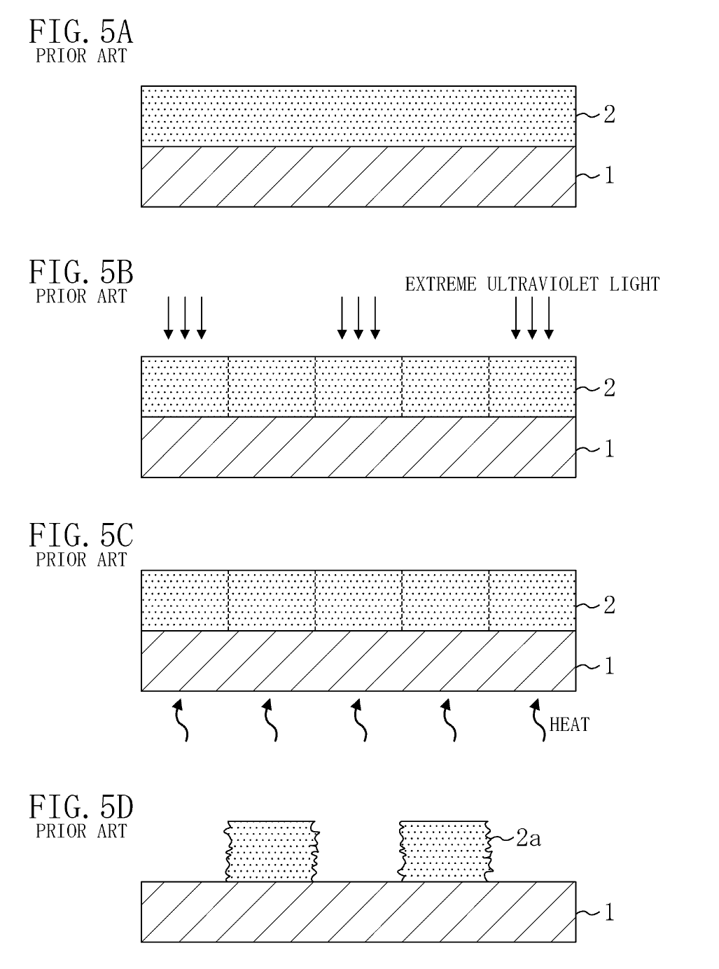

FIG. 6 is a plan view showing a resist pattern obtained with the conventional pattern formation method.

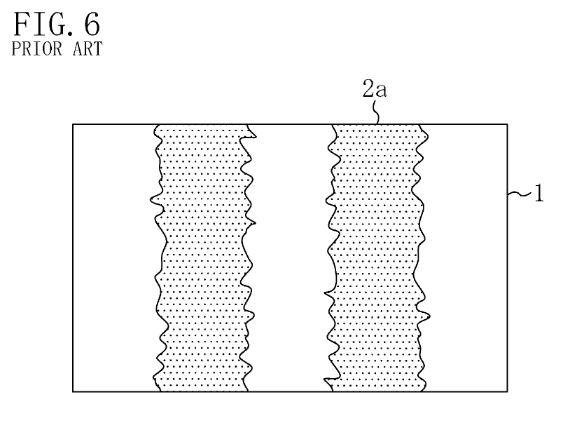

### DETAILED DESCRIPTION

### First Exemplary Embodiment

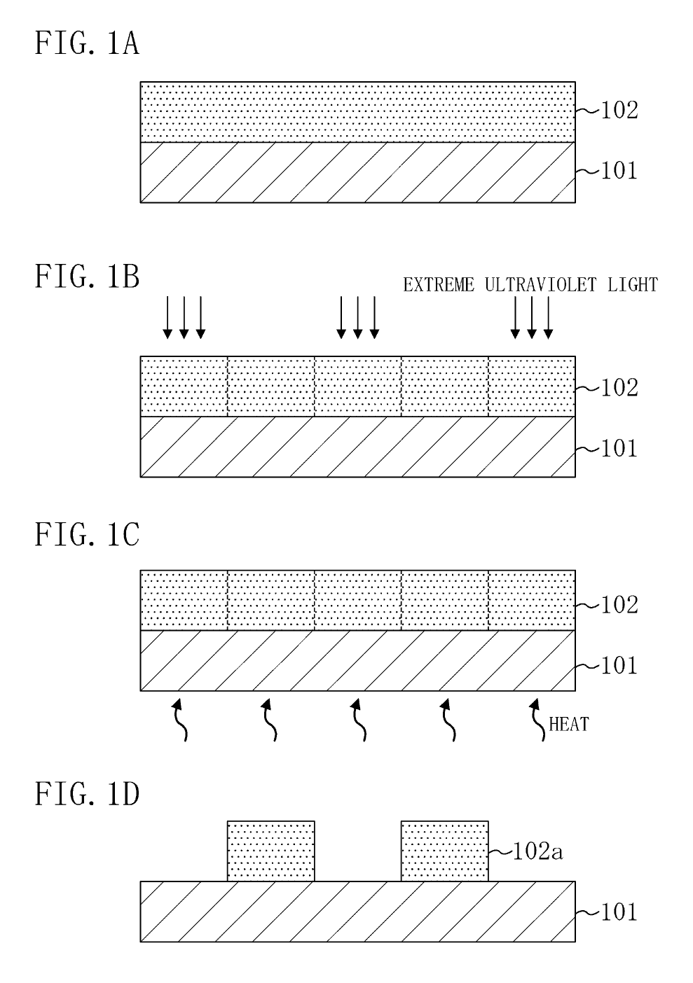

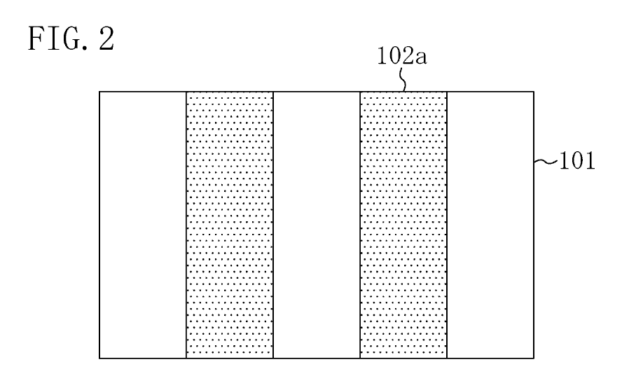

A pattern formation method according to a first exemplary embodiment will be described hereinafter with reference to FIGS. 1A-1D and 2.

First, a positive chemically amplified positive resist material having the following composition is prepared.

Base polymer: poly(cyclohexylethyl methacrylate (60 mol %)-γ-butyrolactone oxystyrene (30 mol %)-2-hydroxy adamantane methacrylate (10 mol %)) (a polymer containing an acid leaving group and a group in which a lactone is replaced with hydrogen in the OH group of phenol) . . . 2 g

Photoacid generator: triphenylsulfonium trifluoromethanesulfonic acid . . . 0.005 g

Quencher: triethanolamine . . . 0.002 g

Solvent: propylene glycol monomethyl ether acetate . . . 20 g

Next, as shown in FIG. 1A, the chemically amplified resist material is applied on a substrate 101, and then is heated at a temperature of 90° C. for 60 seconds, thereby forming a resist film 102 with a thickness of 60 nm.

Then, as shown in FIG. 1B, the resist film 102 is irradiated with exposure light of extreme ultraviolet light (EUV) having a numerical aperture (NA) of 0.25 and a wavelength of 13.5 nm through a mask (not shown), thereby performing pattern exposure. In this process, the mask is a reflective mask, and the light exposure is performed in a high-vacuum atmosphere.

After the pattern exposure, as shown in FIG. 1C, the resist film 102 is heated with a hot plate at a temperature of 105° C. for 60 seconds.

Thereafter, the heated resist film 102 is developed with a 2.38 wt. % tetramethylammonium hydroxide developer, thereby obtaining a resist pattern 102a made of an unexposed portion of the resist film 102 and having a line width of 30 nm, as shown in FIGS. 1D and 2.

As described above, in the first exemplary embodiment, poly(cyclohexylethyl methacrylate (60 mol %)-γ-butyrolactone oxystyrene (30 mol %)-2-hydroxy adamantane methacrylate (10 mol %)) is used as a base polymer of a chemically amplified resist material. Since the base polymer forming the chemically amplified resist material of the first exemplary embodiment includes a group in which a lactone is replaced with hydrogen in the OH group of phenol, the OH group of phenol is spatially stable, resulting in that transmission of an acid is restricted. In addition, the acid is trapped by unpaired electrons in cyclic ester of the lactone, and thus diffusion of the acid is reduced. Accordingly, the generated acid reacts with an adjacent acid leaving group, thus obtaining a resist pattern 102a having a desired shape with a pattern roughness reduced to about 3 nm with a standard deviation (3σ).

### Second Exemplary Embodiment

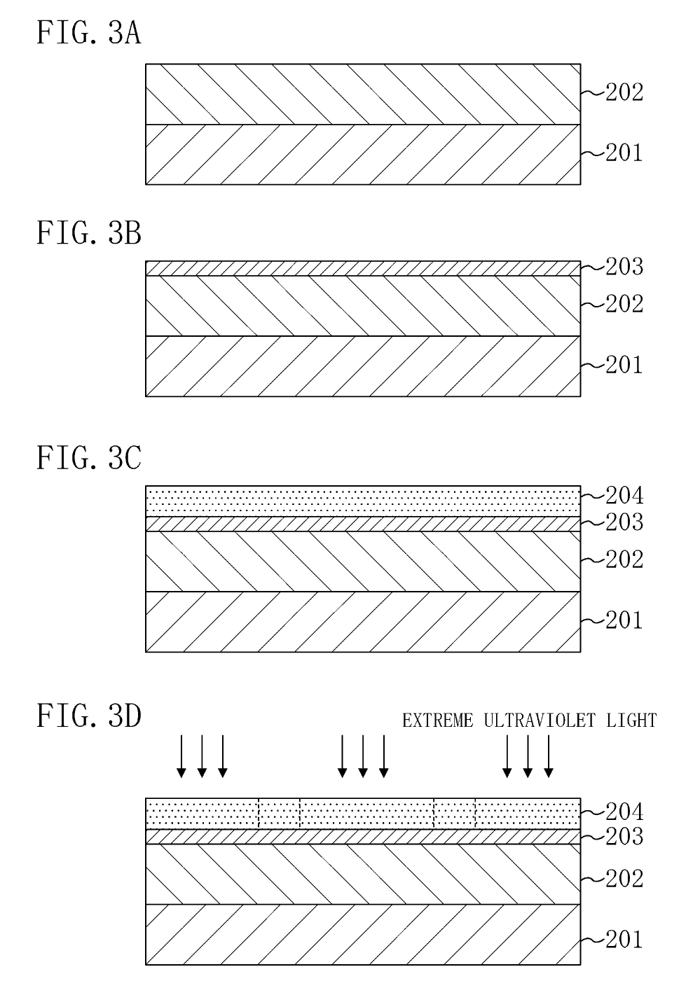

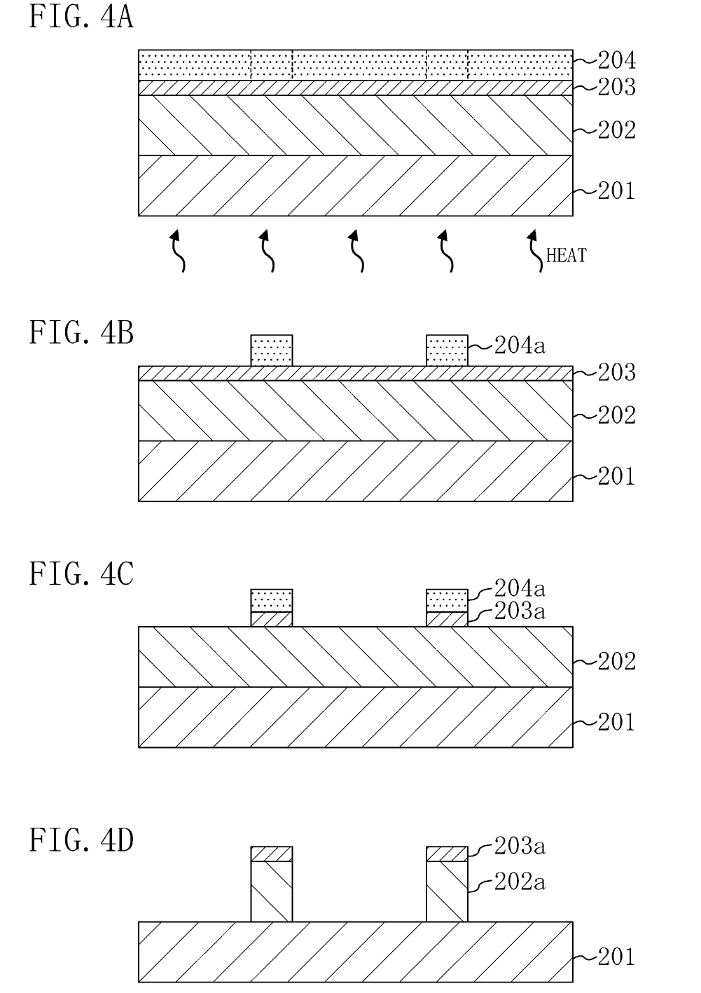

A pattern formation method according to a second exemplary embodiment will be described hereinafter with reference to FIGS. 3A-3D and 4.

First, as shown in FIG. 3A, a novolac resin solution is applied onto a substrate 201, and the substrate 201 is heated (hard-baked) at a temperature of 200° C. for 180 seconds, thereby forming a lower film 202 with a thickness of 100 nm.

Then, as shown in FIG. 3B, with chemical vapor deposition (CVD), for example, an intermediate film 203 made of silicon dioxide (SiO₂) or its precursor with a thickness of about 15 nm is formed on the lower film 202.

Thereafter, as shown in FIG. 3C, a positive chemically amplified positive resist material having the following composition is applied onto the intermediate film 203.

Base polymer: poly(1-ethoxyethyl oxystyrene (45 mol %)-δ-pentylolactone oxystyrene (20 mol %)-hydroxystyrene (35 mol %)) (a polymer containing an acid leaving group and a group in which a lactone is replaced with hydrogen in the OH group of phenol) . . . 2 g

Photoacid generator: triphenylsulfonium nonafluoromethanesulfonic acid . . . 0.005 g

Quencher: triethanolamine . . . 0.002 g

Solvent: propylene glycol monomethyl ether acetate . . . 20 g

Subsequently, the substrate is heated at a temperature of 90° C. for 60 seconds, thereby forming a resist film 204 with a thickness of 30 nm on the intermediate film 203.

Thereafter, a shown in FIG. 3D, the resist film 204 is irradiated with exposure light of extreme ultraviolet light (EUV) having a numerical aperture (NA) of 0.25 and a wavelength of 13.5 nm through a mask (not shown), thereby performing pattern exposure. In this process, the mask is a reflective mask, and the light exposure is performed in a high-vacuum atmosphere.

After the pattern exposure, as shown in FIG. 4A, the resist film 204 is heated with a hot plate at a temperature of 100° C. for 60 seconds.

Thereafter, the heated resist film 204 is developed with a 2.38 wt. % tetramethylammonium hydroxide developer, thereby obtaining a resist pattern 204a made of an unexposed portion of the resist film 204 and having a line width of 25 nm, as shown in FIG. 4B.

Subsequently, as shown in FIG. 4C, the intermediate film 203 is etched with a fluorine-based gas using the resist pattern 204a as a mask, thereby obtaining a first pattern 203a out of the intermediate film 203.

Then, as shown in FIG. 4D, the lower film 202 is etched with an oxygen-based gas using the first pattern 203a as a mask, thereby obtaining a second pattern 202a out of the lower film 202. In this process, the resist pattern 204a is removed through etching in etching the lower film 202. On the other hand, since the first pattern 203a formed out of the intermediate film 203 has a sufficient etching resistance with respect to the oxygen-based gas used for etching of the lower film 202, the second pattern 202a with a desired shape can be formed.

As described above, in the second exemplary embodiment, poly(1-ethoxyethyl oxystyrene (45 mol %)-δ-pentylolactone oxystyrene (20 mol %)-hydroxystyrene (35 mol %)), which is a polymer containing an acid leaving group and a group in which a lactone is replaced with hydrogen in the OH group of phenol, is used as a base polymer of a chemically amplified resist material in a multilayer resist process. Since the base polymer forming the chemically amplified resist material of the second exemplary embodiment includes a group in which a lactone is replaced with hydrogen in the OH group of phenol, the OH group of phenol is spatially stable, resulting in that transmission of an acid is restricted. In addition, the acid is trapped by unpaired electrons in cyclic ester of the lactone, and thus diffusion of the acid is reduced. Accordingly, the generated acid reacts with an adjacent acid leaving group, thus obtaining a resist pattern 204a having a desired shape with a pattern roughness reduced. The roughness of each of the first pattern 203a and the second pattern 202a etched using the resist pattern 204a with the desired shape as a mask is also reduced to about 2 nm with a standard deviation (3σ). As a result, the first pattern 203a and the second pattern 202a each having a desired shape can be obtained.

In the first and second exemplary embodiments, the lactones to be replaced with hydrogen in the OH group of phenol in the base polymers forming the chemically amplified resist materials are γ-butyrolactone and β-pentylolactone, respectively. However, the present disclosure is not limited to these embodiments. Alternatively, α-lactone (e.g., α-ethylolactone) or β-lactone (e.g., β-propylolactone) may be used, for example.

In each of the first and second exemplary embodiments, a 1-ethoxyethyl group, which is a cyclohexylmethyl group or an acetal group, is used as an acid leaving group forming the chemically amplified resist material. However, the present disclosure is not limited to these embodiments. Alternatively, a cyclohexylethyl group, a cyclopentylmethyl group, or a cyclopentylethyl group may be used. In the case of using an acetal group, instead of the 1-ethoxyethyl group, a methoxymethyl group or a 1-ethoxymethyl group may be used.

The extreme ultraviolet light used as exposure light may be replaced with an electron beam or KrF excimer laser light.

A chemically amplified resist material and a pattern formation method using the resist material according to the present disclosure can achieve a fine pattern with a desired shape by reducing roughness of a resist pattern, and thus are useful for, for example, fine pattern formation in fabrication processes of semiconductor devices or other processes.

What is claimed is:

1. A pattern formation method, comprising the steps of:
forming a resist film on a substrate, the resist film being made of a chemically amplified resist material including a polymer containing an acid leaving group and a group in which a lactone is replaced with hydrogen in an OH group of phenol;
selectively irradiating the resist film with exposure light, thereby performing pattern exposure;
heating the resist film subjected to the pattern exposure; and
developing the heated resist film, thereby forming a resist pattern out of the resist film.

2. A pattern formation method, comprising the steps of:
forming a lower film on a substrate;
forming an intermediate film on the lower film;
forming a resist film on the intermediate film, the resist film being made of a chemically amplified resist material including a polymer containing an acid leaving group and a group in which a lactone is replaced with hydrogen in an OH group of phenol;
selectively irradiating the resist film with exposure light, thereby performing pattern exposure;
heating the resist film subjected to the pattern exposure;
developing the heated resist film, thereby forming a resist pattern out of the resist film;
etching the intermediate film using the resist pattern as a mask, thereby forming a first pattern out of the intermediate film; and
etching the lower film using the first pattern as a mask, thereby forming a second pattern out of the lower film.

3. The pattern formation method of claim 2, wherein the lower film is a hard-baked organic film.

4. The pattern formation method of claim 3, wherein the intermediate film is made of either silicon oxide or a precursor of silicon oxide.

5. The pattern formation method of claim 1, wherein the lactone is one of α-lactone, β-lactone, γ-lactone, or δ-lactone.

6. The pattern formation method of claim 5, wherein the α-lactone is α-ethylolactone.

7. The pattern formation method of claim 5, wherein the β-lactone is β-propylolactone.

8. The pattern formation method of claim 5, wherein the γ-lactone is γ-butyrolactone.

9. The pattern formation method of claim 5, wherein the δ-lactone is δ-pentylolactone.

10. The pattern formation method of claim 5, wherein the acid leaving group is one of an acetal group, a cyclohexylmethyl group, a cyclohexylethyl group, a cyclopentylmethyl group, or a cyclopentylethyl group.

11. The pattern formation method of claim 10, wherein the acetal group is one of a 1-ethoxyethyl group, a methoxymethyl group, or a 1-ethoxymethyl group.

12. The pattern formation method of claim 11, wherein the exposure light is one of extreme ultraviolet light, an electron beam, or KrF excimer laser light.

13. A chemically amplified resist material, comprising a polymer containing an acid leaving group and a group in which a lactone is replaced with hydrogen in an OH group of phenol.

14. The chemically amplified resist material of claim 13, wherein the lactone is one of α-lactone, β-lactone, γ-lactone, or δ-lactone.

15. The chemically amplified resist material of claim 14, wherein the α-lactone is α-ethylolactone.

16. The chemically amplified resist material of claim 14, wherein the β-lactone is β-propylolactone.

17. The chemically amplified resist material of claim 14, wherein the γ-lactone is γ-butyrolactone.

18. The chemically amplified resist material of claim 14, wherein the δ-lactone is δ-pentylolactone.

19. The chemically amplified resist material of claim 14, wherein the acid leaving group is one of an acetal group, a cyclohexylmethyl group, a cyclohexylethyl group, a cyclopentylmethyl group, or a cyclopentylethyl group.

20. The chemically amplified resist material of claim 19, wherein the acetal group is one of a 1-ethoxyethyl group, a methoxymethyl group, or a 1-ethoxymethyl group.
